(19) United States
(12) Patent Application Publication
(10) Pub. No.: US 2026/0296013 A1
(43) Pub. Date: Oct. 1, 2026

(54) PIEZOELECTRIC DEVICE AND LIQUID EJECTION HEAD

(71) Applicant: SEIKO EPSON CORPORATION, Tokyo (JP)

(72) Inventors: Misaki ADACHI, MATSUMOTO-SHI (JP); Shiro YAZAKI, CHINO-SHI (JP); Takatoshi YAMAZAKI, SHIOJIRI-SHI (JP)

(21) Appl. No.: 19/577,837

(22) Filed: Mar. 25, 2026

(30) Foreign Application Priority Data
Mar. 28, 2025 (JP) 2025-055907

(51) Int. Cl. B41J 2/14; H10N 30/20; H10N 30/88

(52) U.S. Cl. CPC B41J 2/14233; H10N 30/2047; H10N 30/883; B41J 2002/14241; B41J 2002/14258

(57) ABSTRACT

A piezoelectric device includes a vibrating plate coupled to a first substrate and partitioning a space with the first substrate, and a piezoelectric element having a first electrode, a piezoelectric layer, and a second electrode laminated in this order along a first direction from the vibrating plate toward the first substrate. When viewed in the first direction, a region where the space and the vibrating plate overlap is an overlapping region, and a region where a partition wall of the first substrate and the vibrating plate overlap is a non-overlapping region. An arm region where the piezoelectric layer is not provided extends from part of the overlapping region to part of the non-overlapping region. A first stress relieving portion is provided in the arm region along a second direction intersecting a longitudinal direction of the arm region.

The present application is based on, and claims priority from JP Application Serial Number 2025-055907, filed Mar. 28, 2025, the disclosure of which is hereby incorporated by reference herein in its entirety.

### BACKGROUND

### 1. Technical Field

The present disclosure relates to a piezoelectric device and a liquid ejection head.

### 2. Related Art

In the related art, a technique for ejecting liquid in a pressure chamber by using a piezoelectric device including a piezoelectric element having two electrodes and a piezoelectric layer interposed between the two electrodes, and a vibrating plate has been proposed. For example, JP-A-2019-123257 discloses a liquid ejection head having a region, corresponding to a region between adjacent pressure chambers in the piezoelectric layer, in which a recess that penetrates the piezoelectric layer or a recess that is relatively thin in the piezoelectric layer is provided. Hereinafter, this region may be referred to as an arm region. By providing the arm region, the piezoelectric element can be smoothly displaced.

In the related art described above, the piezoelectric element can be smoothly displaced by providing the arm region. However, stress is concentrated in the arm region with the displacement of the piezoelectric element, and there is a possibility that a crack occurs in the arm region.

### SUMMARY

A piezoelectric device according to a preferred aspect of the present disclosure includes a vibrating plate coupled to a first substrate and configured to partition a space together with the first substrate, and a piezoelectric element in which a first electrode, a piezoelectric layer, and a second electrode are laminated in this order along a first direction from the vibrating plate toward the first substrate, the piezoelectric element being disposed on a side of the vibrating plate opposite to the space, in which when a region in which the space and the vibrating plate overlap each other when viewed in the first direction is defined as an overlapping region, and a region in which a partition wall of the first substrate that partitions the space and the vibrating plate overlap each other when viewed in the first direction is defined as a non-overlapping region, an arm region, which is a region in which the piezoelectric layer is not provided when viewed in the first direction, is located from a portion of the overlapping region to a portion of the non-overlapping region, and a first stress relieving portion is provided along a second direction intersecting a longitudinal direction of the arm region in the arm region.

A liquid ejection head according to a preferred aspect of the present disclosure includes the piezoelectric device described above.

### BRIEF DESCRIPTION OF THE DRAWINGS

FIG. 1 is a schematic view illustrating a configuration example of a liquid ejection apparatus.

FIG. 2 is an exploded perspective view of a liquid ejection head.

FIG. 3 is a sectional view of the liquid ejection head.

FIG. 4 is a plan view of the liquid ejection head as viewed in a Z2 direction.

FIG. 5 is an enlarged sectional view of the vicinity of a piezoelectric device illustrated in FIG. 3.

FIG. 6 is an enlarged view of a range illustrated in FIG. 4 in the liquid ejection head.

FIG. 7 is a sectional view taken along a line VII-VII in FIG. 6.

FIG. 8 is a sectional view taken along a VIII-VIII line in FIG. 6.

FIG. 9 is an enlarged sectional view of the vicinity of a piezoelectric device.

FIG. 10 is an enlarged view of the range illustrated in FIG. 4 in a liquid ejection head according to a second embodiment.

FIG. 11 is a sectional view taken along line XI-XI in FIG. 10.

FIG. 12 is a sectional view taken along line XII-XII in FIG. 10.

### DESCRIPTION OF EMBODIMENTS

Hereinafter, embodiments for carrying out the present disclosure are described with reference to the drawings. However, in each drawing, a dimension and a scale of each section are appropriately different from actual ones. In addition, since embodiments to be described below are preferred specific examples of the present disclosure, various technically preferable limitations are imposed. However, the scope of the present disclosure is not limited to these embodiments unless there is a description in the following description that particularly limits the present disclosure.

For the sake of convenience, the following description will be made by using an X-axis, a Y-axis, and a Z-axis that intersect with each other, as appropriate. In addition, one direction along the X-axis is an X1 direction, and a direction opposite to the X1 direction is an X2 direction. Similarly, directions opposite to each other along the Y-axis are a Y1 direction and a Y2 direction. In addition, directions opposite to each other along the Z-axis are a Z1 direction and a Z2 direction.

Here, typically, the Z-axis is a vertical axis, and the Z2 direction corresponds to a downward direction in the vertical direction. In other words, the Z2 direction is a gravity direction. However, the Z-axis does not have to be a vertical axis and may be inclined with respect to the vertical axis. The X-axis, the Y-axis, and the Z-axis are typically orthogonal to each other, but are not limited thereto. For example, the X-axis, the Y-axis, and the Z-axis may intersect with each other at an angle in a range of 80 degrees to 100 degrees.

### 1. First Embodiment

### 1-1. Outline of Liquid Ejection Apparatus 100

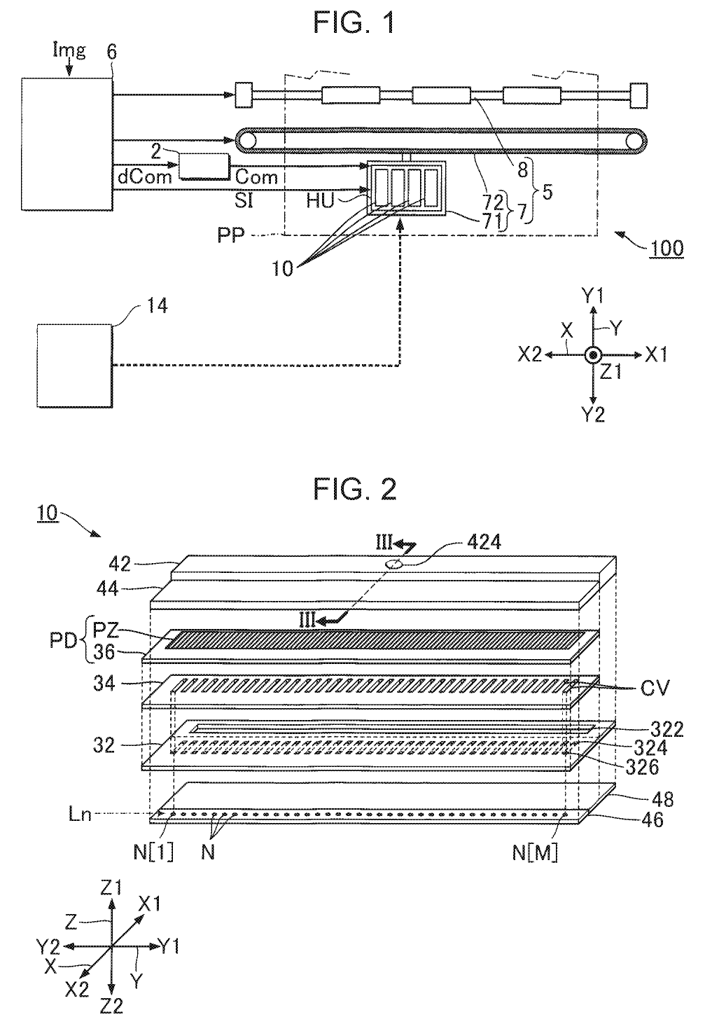

FIG. 1 is a schematic diagram illustrating a configuration example of a liquid ejection apparatus 100. The liquid ejection apparatus 100 is an ink jet printing apparatus that ejects ink, which is an example of liquid, as liquid droplets onto a medium PP. The liquid ejection apparatus 100 of the present embodiment is an ink jet printing apparatus that ejects ink, which is an example of liquid, onto the medium PP. The medium PP is typically printing paper; however, any print target such as a resin film or a woven fabric can be utilized as the medium PP.

As illustrated in FIG. 1, the liquid ejection apparatus 100 includes a drive signal generation circuit 2, a liquid container 14, a control module 6, a moving mechanism 5, and a liquid ejection module HU having a plurality of liquid ejection heads 10. In the present embodiment, the liquid ejection module HU includes four liquid ejection heads 10. The drive signal generation circuit 2 is an example of a "drive control unit".

The liquid container 14 is a container for storing the ink. Specific aspects of the liquid container 14 include, for example, a cartridge detachable from the liquid ejection apparatus 100, a bag-shaped ink pack formed of a flexible film, and an ink tank refillable with ink. The type of the ink stored in the liquid container 14 is optional.

The control module 6 includes, for example, one or more processing circuits, such as a CPU or an FPGA, and one or more storage circuits, such as a semiconductor memory. CPU is an abbreviation for Central Processing Unit. FPGA is an abbreviation for a Field Programmable Gate Array. Various programs and various data are stored in the storage circuit. The processing circuit realizes various control by executing the program and appropriately using the data.

The moving mechanism 5 changes a relative position between the medium PP and the liquid ejection module HU. The moving mechanism 5 includes a transport mechanism 8 and a head moving mechanism 7.

The transport mechanism 8 transports the medium PP in the Y2 direction under the control of the control module 6. In the example illustrated in FIG. 1, the transport mechanism 8 includes a transport roller that is elongated along the X-axis, and a motor that rotates the transport roller. The transport mechanism 8 is not limited to the configuration in which a transport roller is used. For example, the transport mechanism 8 may use a drum or an endless belt that transports the medium PP while the medium PP is attracted to an outer circumferential surface by an electrostatic force or the like.

The head moving mechanism 7 reciprocates the liquid ejection module HU in the X1 direction and the X2 direction under the control of the control module 6. In the present embodiment, the X1 direction and the X2 direction are the main scanning directions, and the Y2 direction is a sub-scanning direction. As described above, the liquid ejection apparatus 100 according to the first embodiment is a serial type liquid ejection apparatus which reciprocates along the X-axis. As illustrated in FIG. 1, the head moving mechanism 7 includes a housing case 71 that accommodates the liquid ejection module HU, and an endless belt 72 to which the housing case 71 is fixed. The liquid container 14 may be housed in the housing case 71 together with the liquid ejection module HU.

The liquid ejection module HU ejects ink from the liquid container 14 toward the medium PP in the Z2 direction from each of the plurality of nozzles N under control of the control module 6.

The control module 6 controls the ejection operation of the liquid ejection head 10. Specifically, the control module 6 generates a print signal SI for controlling the liquid ejection head 10, a waveform designation signal dCom for controlling the drive signal generation circuit 2, a signal for controlling the transport mechanism 8, and a signal for controlling the head moving mechanism 7.

The waveform designation signal dCom is a digital signal for defining a waveform of a drive signal Com. The drive signal Com is an analog signal for driving a piezoelectric element PZ, which will be described later with reference to FIG. 2. The drive signal generation circuit 2 includes a D/A conversion circuit and generates the drive signal Com having the waveform defined by the waveform designation signal dCom.

The print signal SI is a digital signal for designating the type of operation of the piezoelectric element PZ. Specifically, the print signal SI designates the type of operation of the piezoelectric element PZ by designating whether or not to supply the drive signal Com to the piezoelectric element PZ. Here, the designation of the type of operation of the piezoelectric element PZ is, for example, designation of whether or not to drive the piezoelectric element PZ, designation of whether or not to eject ink from the piezoelectric element PZ when the piezoelectric element PZ is driven, or designation of the amount of ink ejected from the piezoelectric element PZ when the piezoelectric element PZ is driven.

First, the control module 6 stores print data Img supplied from a host computer such as a personal computer or a digital camera in a storage circuit of the control module 6. Next, the control module 6 generates various control signals such as the print signal SI, the waveform designation signal dCom, a signal for controlling the transport mechanism 8, and a signal for controlling the head moving mechanism 7 based on various data such as the print data Img stored in the storage circuit. The control module 6 controls the liquid ejection module HU such that the piezoelectric element PZ is driven while controlling the transport mechanism 8 and the head moving mechanism 7 such that the relative position of the medium PP with respect to the liquid ejection module HU is changed based on various control signals and various data stored in the storage circuit of the control module 6. Accordingly, the control module 6 adjusts the presence or absence of the ejection of the ink from the piezoelectric element PZ, the ejection amount of the ink, the ejection timing of the ink, and the like, and controls the execution of the printing process of forming the image corresponding to the print data Img on the medium PP.

### 1-2. Outline of Liquid Ejection Head 10

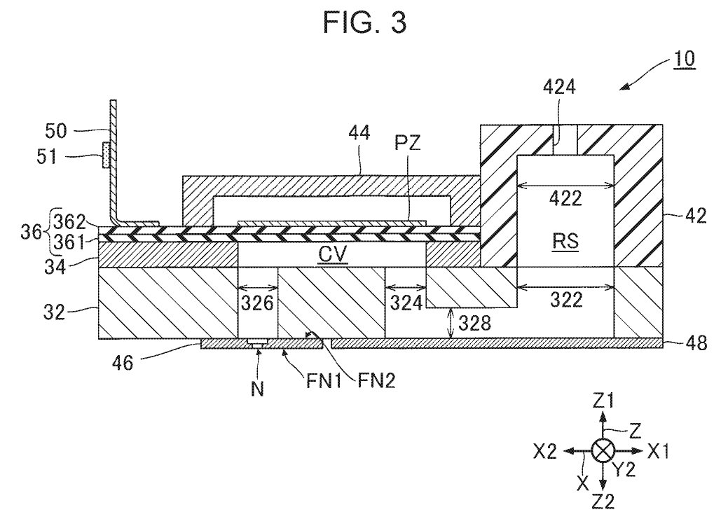

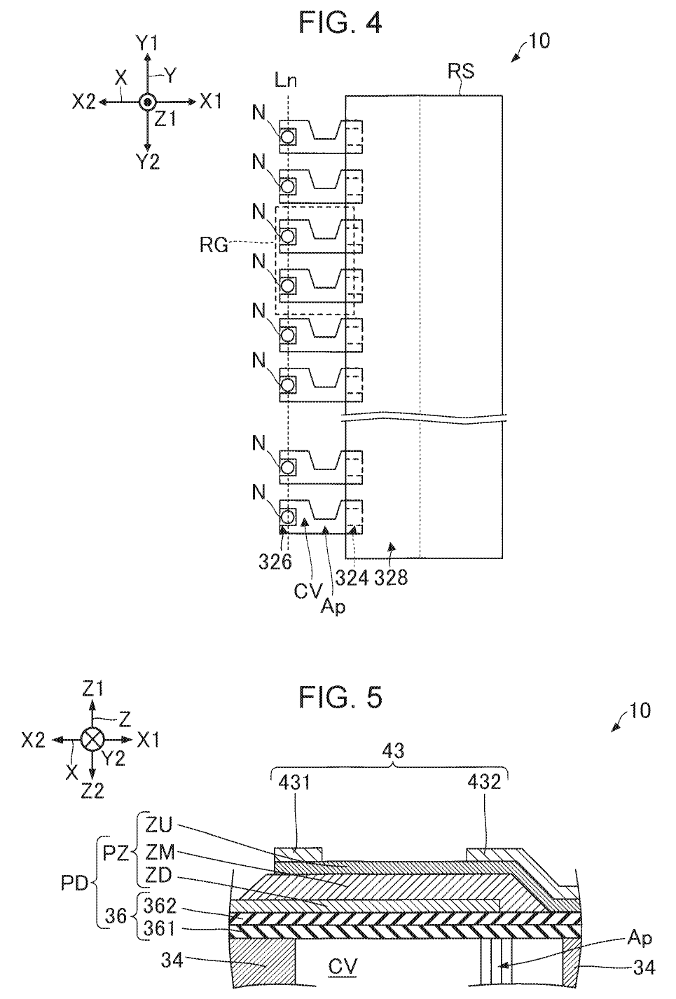

Hereinafter, an outline of the liquid ejection head 10 will be described with reference to FIGS. 2, 3, and 4. FIG. 2 is an exploded perspective view of the liquid ejection head 10. FIG. 3 is a sectional view of the liquid ejection head 10. FIG. 4 is a plan view of the liquid ejection head 10 as viewed in the Z2 direction. The view illustrated in FIG. 3 is a sectional view illustrating a state in which the liquid ejection head 10 is cut along the line III-III in FIG. 2 and the section is viewed in the Y2 direction. The III-III section is parallel to the XZ plane and passes through an inlet 424 described later.

As illustrated in FIGS. 2 and 3, the liquid ejection head 10 includes a substantially rectangular communication plate 32 which is long along the Y-axis. A pressure chamber substrate 34, a vibrating plate 36, the M piezoelectric elements PZ, a housing portion 42, and a sealing member 44 are installed on a surface of the communication plate 32 in the Z1 direction. In other words, the communication plate 32 is stacked on a surface of the pressure chamber substrate 34 in the Z2 direction. M is an integer of 2 or more. A nozzle substrate 46 and a compliance substrate 48 are installed on a surface of the communication plate 32 in the Z2 direction. Each element of the liquid ejection head 10 is schematically a plate-shaped member which is long along the Y-axis in the same manner as the communication plate 32, and is bonded to each other using an adhesive. The pressure chamber substrate 34 is an example of a "first substrate".

As illustrated in FIG. 2, the nozzle substrate 46 is a plate-shaped member in which M nozzles N arranged along a nozzle row Ln parallel to the Y-axis are formed. The arrangement direction in which the M nozzles N are arranged is a direction along the Y-axis. The nozzle substrate 46 is, for example, a silicon substrate. As illustrated in FIG. 3, the nozzle substrate 46 has a surface FN1 facing the Z2 direction and a surface FN2 facing the Z1 direction. Each of the nozzles N is a through-hole through which ink passes.

The communication plate 32 is a plate-shaped member provided with a flow path through which the ink flows. As illustrated in FIGS. 2 and 3, an opening 322, a second communication path 324, and a first communication path 326 are formed in the communication plate 32. The opening 322 is a through-hole commonly provided for the M nozzles N along the Y-axis when viewed in the Z2 direction. Hereinafter, viewing in the Z2 direction may be referred to as "plan view". The second communication path 324 and the first communication path 326 are through-holes individually formed for each nozzle N. In addition, as illustrated in FIG. 3, a common flow path 328 extending over the M second communication paths 324 is formed on the surface of the communication plate 32 in the Z2 direction. The common flow path 328 is a flow path that causes the opening 322 and the M second communication paths 324 to communicate with each other. The Z2 direction is a direction from the vibrating plate 36 toward the pressure chamber substrate 34, and is an example of a "first direction".

The communication plate 32 and the pressure chamber substrate 34 are formed by processing a silicon single crystal substrate by a semiconductor manufacturing technique such as etching. However, a manufacturing method of each element of the liquid ejection head 10 is optional.

The housing portion 42 is a structure manufactured by injection molding a resin material, for example, and is fixed to the surface of the communication plate 32 in the Z1 direction. As illustrated in FIG. 3, the housing portion 42 is formed with an accommodation portion 422 and an inlet 424. The accommodation portion 422 is a recessed portion having an outer shape corresponding to the opening 322 of the communication plate 32. The inlet 424 is a through-hole that communicates with the accommodation portion 422. As understood from FIG. 3, a space in which the opening 322 of the communication plate 32 and the accommodation portion 422 of the housing portion 42 are brought into communication with each other functions as a liquid storage chamber RS. The ink supplied from the liquid container 14 and passing through the inlet 424 is stored in the liquid storage chamber RS.

The compliance substrate 48 has a function of buffering the vibration of ink in the liquid storage chamber RS. The compliance substrate 48 includes, for example, a flexible sheet member capable of elastic deformation. Specifically, the compliance substrate 48 is installed on a surface of the communication plate 32 in the Z2 direction so as to seal the opening 322 of the communication plate 32, the common flow path 328, and the plurality of second communication paths 324 and to constitute a bottom surface of the liquid storage chamber RS.

As illustrated in FIGS. 2 and 3, the pressure chamber substrate 34 is a plate-shaped member in which M pressure chambers CV respectively corresponding to the M nozzles N are formed. The M pressure chambers CV are arranged to be spaced apart from each other along the Y-axis. Each pressure chamber CV is partitioned by the pressure chamber substrate 34 and the vibrating plate 36. Each pressure chamber CV is an opening extending along the X-axis. An end portion of the pressure chamber CV in the X1 direction overlaps one second communication path 324 in plan view, and an end portion of the pressure chamber CV in the X2 direction overlaps one first communication path 326 of the communication plate 32 in plan view. In addition, a restrictor portion Ap is provided in each of the M pressure chambers CV. The restrictor portion Ap is a flow path formed to be narrower than other regions in the pressure chamber CV.

The vibrating plate 36 is installed on a surface of the pressure chamber substrate 34 in a direction opposite to a surface facing the communication plate 32. The vibrating plate 36 is a plate-shaped member that is elastically deformable. As illustrated in FIG. 3, the vibrating plate 36 is configured as a laminate of an elastic layer 361 and an insulating layer 362. The insulating layer 362 is positioned in a direction opposite to the pressure chamber substrate 34 when viewed from the elastic layer 361. The elastic layer 361 is formed of silicon oxide as a main constituent material. The insulating layer 362 is made of a material different from that of the elastic layer 361. For example, the insulating layer 362 is formed of zirconium oxide. The insulating layer 362 suppresses diffusion of moisture and lead into the elastic layer 361. The elastic layer 361 is an example of a "first layer", and the insulating layer 362 is an example of a "second layer".

As understood from FIG. 3, the communication plate 32 and the vibrating plate 36 face each other with a space therebetween inside each pressure chamber CV. The pressure chamber CV is positioned between the communication plate 32 and the vibrating plate 36, and is a space for applying pressure to the ink accommodated in the pressure chamber CV. The vibrating plate 36 forms a part of a wall surface of the pressure chamber CV. The ink stored in the liquid storage chamber RS is branched from the common flow path 328 to each of the second communication paths 324 and is supplied to and accommodated in the M pressure chambers CV in parallel. That is, the liquid storage chamber RS functions as a common liquid chamber for supplying the ink to a plurality of pressure chambers CV.

As illustrated in FIGS. 2 and 3, M piezoelectric elements PZ respectively corresponding to the M nozzles N are installed on a surface of the vibrating plate 36 in a direction opposite to the pressure chamber substrate 34. The vibrating plate 36 and the M piezoelectric elements PZ form a piezoelectric device PD. The piezoelectric device PD may include a sealing member 44. Each of the piezoelectric elements PZ is an actuator that is deformed by the supply of the drive signal Com, and is formed in a long shape along the X-axis. The M piezoelectric elements PZ are arranged along the Y-axis to correspond to the M pressure chambers CV. When the vibrating plate 36 vibrates in conjunction with the deformation of the piezoelectric element PZ, the pressure in the pressure chamber CV varies. The piezoelectric element PZ is a drive element that vibrates the vibrating plate 36. The piezoelectric element PZ includes two electrodes and a piezoelectric layer ZM interposed between the two electrodes. The configuration of the piezoelectric element PZ will be described later with reference to FIG. 5.

Hereinafter, the first, second, ..., and M-th may be used in order to distinguish each of the M piezoelectric elements PZ. In addition, the m-th piezoelectric element PZ may be referred to as a piezoelectric element PZ[m]. The variable m is an integer of 1 or more and M or less. In addition, when a constituent element, a signal, or the like of the liquid ejection apparatus 100 corresponds to the piezoelectric element PZ, a subscript [m] indicating correspondence to the m-th may be added to a symbol for representing the constituent element, the signal, or the like. For example, the m-th nozzle N may be expressed as a nozzle N[m]. As illustrated in FIG. 2, among the M nozzles N, the nozzle N positioned in the most Y2 direction is expressed as a nozzle N[1] and the nozzle N positioned in the most Y1 direction is expressed as a nozzle N[M].

When the vibrating plate 36 vibrates in conjunction with the deformation of the piezoelectric element PZ, the pressure in the pressure chamber CV varies, and the ink filled in the pressure chamber CV is ejected through the first communication path 326 and the nozzle N.

As illustrated in FIGS. 2 and 3, the sealing member 44 is a structure that protects the M piezoelectric elements PZ from the outside air and reinforces the mechanical strength of the pressure chamber substrate 34 and the vibrating plate 36. The sealing member 44 is fixed to the surface of the vibrating plate 36 with, for example, an adhesive. M piezoelectric elements PZ are accommodated inside a recessed portion formed on a surface of the sealing member 44 facing the vibrating plate 36.

As illustrated in FIG. 3, a wiring substrate 50 is bonded to the surface of the vibrating plate 36. The wiring substrate 50 is a mounting component on which a plurality of wiring lines for electrically coupling the control module 6 and the liquid ejection head 10 are formed. For example, a flexible wiring substrate 50 such as an FPC or an FFC is preferably employed. FPC is an abbreviation for Flexible Printed Circuit. FFC is an abbreviation for Flexible Flat Cable. A drive circuit 51 is mounted on the wiring substrate 50. The drive circuit 51 is an electric circuit that switches whether or not to supply the drive signal Com to the piezoelectric element PZ under the control of the print signal SI.

### 1-3. Configuration of Piezoelectric Device PD

In plan view, by having an arm region AR, which is a region in which the piezoelectric layer ZM is not provided at a portion overlapping a partition wall of the pressure chamber substrate 34 between two adjacent pressure chambers CV, the piezoelectric element PZ can be smoothly displaced, and displacement efficiency of the piezoelectric element PZ can be increased. However, by having the arm region AR, stress is concentrated in the arm region AR with displacement of the piezoelectric element PZ, and a crack may occur in the arm region AR. Therefore, in the present embodiment, a stress relieving portion SR for relieving the stress acting on the arm region AR is provided in a part or the whole of the arm region AR. The vicinity of the piezoelectric element PZ including the stress relieving portion SR will be described with reference to FIGS. 5 to 8.

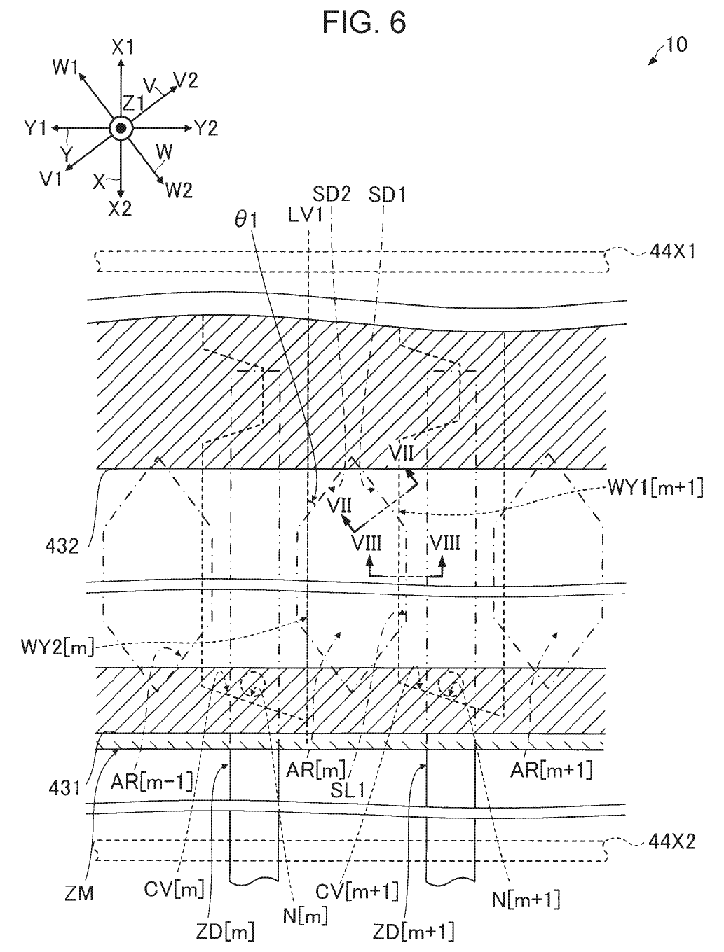

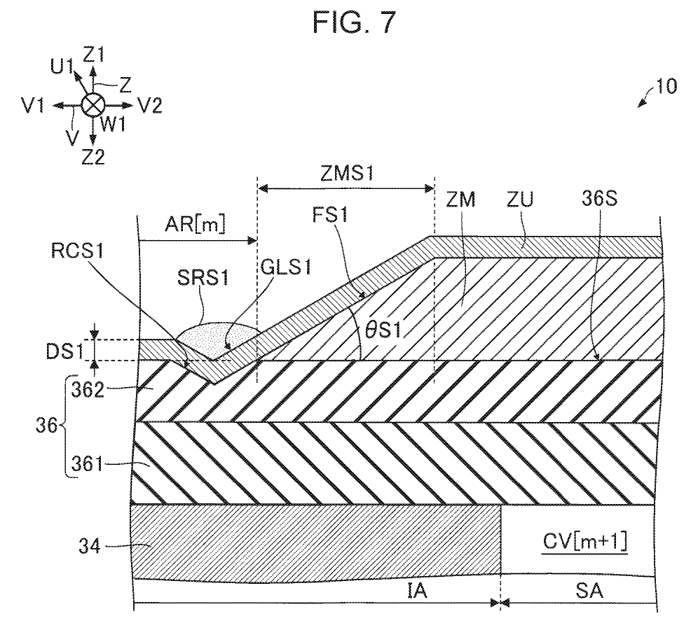

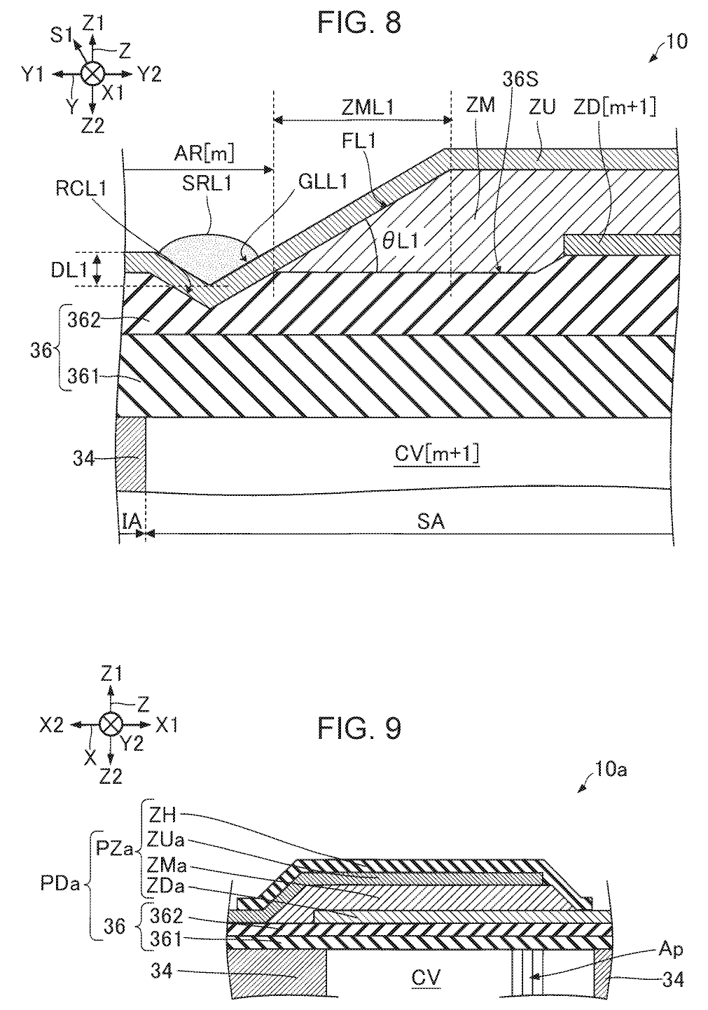

FIG. 5 is an enlarged sectional view of the vicinity of the piezoelectric device PD illustrated in FIG. 3. FIG. 6 is an enlarged view of a range RG illustrated in FIG. 4 in the liquid ejection head 10. However, in order to prevent the drawing from being complicated, the sealing member 44 is not illustrated in FIG. 6. In addition, in FIG. 6, a region 44X2 in which an edge positioned in the Z2 direction among the edges of the sealing member 44 facing the X2 direction is bonded to the vibrating plate 36 and a region 44X1 in which the edge positioned in the X1 direction is bonded to the vibrating plate 36 are displayed. FIG. 7 is a sectional view taken along a line VII-VII in FIG. 6. FIG. 8 is a sectional view taken along a VIII-VIII line in FIG. 6.

As illustrated in FIG. 5, the piezoelectric element PZ is a laminate in which the piezoelectric layer ZM is interposed between a lower electrode ZD to which the drive signal Com is supplied and an upper electrode ZU to which a predetermined reference potential VBS is supplied. The piezoelectric element PZ is, for example, a portion where the lower electrode ZD, the upper electrode ZU, and the piezoelectric layer ZM overlap each other in plan view. Further, the pressure chamber CV is provided in the Z2 direction of the piezoelectric element PZ. In FIG. 6, in order to prevent the drawing from being complicated, hatching of the piezoelectric layer ZM is partially omitted. The lower electrode ZD is an example of a "first electrode", and the upper electrode ZU is an example of a "second electrode".

As described above, the piezoelectric element PZ is driven and deformed according to the potential change of the drive signal Com. The vibrating plate 36 vibrates in conjunction with the deformation of the piezoelectric element PZ. When the vibrating plate 36 vibrates, the pressure in the pressure chamber CV varies. When the pressure in the pressure chamber CV varies, the ink filled in the pressure chamber CV is ejected from the nozzle N through the first communication path 326.

As understood from FIG. 6, the upper electrode ZU is commonly provided for the M pressure chambers CV. Therefore, the upper electrode ZU is also referred to as a common electrode. The upper electrode ZU is strip-shaped and extends in a direction along the Y-axis so as to be continuous with the M pressure chambers CV. On the other hand, the lower electrodes ZD are individually provided for the M pressure chambers CV. Therefore, the lower electrode ZD is also referred to as an individual electrode. As materials for the upper electrode ZU and the lower electrode ZD, metal materials such as platinum (Pt), iridium (Ir), aluminum (Al), nickel (Ni), gold (Au), copper (Cu), and the like, or alloys and the like can be exemplified. The upper electrode ZU and the lower electrode ZD may be a single layer or a plurality of layers.

The piezoelectric layer ZM is commonly provided for the M pressure chambers CV, and has the arm region AR as described above. Similarly to the upper electrode ZU, the piezoelectric layer ZM is strip-shaped and extends in a direction along the Y-axis so as to be continuous with the M pressure chambers CV. The piezoelectric layer ZM is formed of a composite oxide. Specifically, the piezoelectric layer ZM is formed of a piezoelectric material having a perovskite crystal structure. As the piezoelectric material, lead titanate (PbTiO₃), lead zirconate titanate (Pb(Zr,Ti)O₃), lead zirconate (PbZrO₃), lead lanthanum titanate ((Pb,La)TiO₃), lead lanthanum zirconate titanate ((Pb,La)(Zr,Ti)O₃), potassium sodium niobate ((K,Na)NbO₃), lead zirconate titanate niobate (Pb(Zr,Ti,Nb)O₃), lead magnesium niobate zirconate titanate (Pb(Zr,Ti)(Mg,Nb)O₃), and the like can be exemplified. The piezoelectric layer ZM may contain a small amount of other elements such as impurities. Further, the piezoelectric layer ZM may be a single layer or a plurality of layers.

In addition, as illustrated in FIG. 5, a deformation restricting portion 43 is provided in the Z1 direction of the upper electrode ZU. The deformation restricting portion 43 includes a first film 431 provided at an end portion of the pressure chamber CV in the X2 direction and a second film 432 provided at an end portion of the pressure chamber CV in the X1 direction in plan view. The first film 431 and the second film 432 are commonly provided for the M pressure chambers CV, and are strip-shaped and extend in a direction along the Y-axis so as to be continuous with the M pressure chambers CV. The first film 431 and the second film 432 are metal films formed of, for example, Au. An adhesion film may be provided between the first film 431 and the second film 432 and the upper electrode ZU to improve adhesion. The adhesion film is formed of, for example, NiCr. The first film 431 and the second film 432 may not be provided.

As illustrated in FIG. 6, an arm region AR is provided which is a region where the upper electrode ZU, the vibrating plate 36, and the pressure chamber CV overlap each other and the lower electrode ZD and the piezoelectric layer ZM do not overlap each other in plan view viewed in the Z2 direction. That is, the arm region AR is a region in which the piezoelectric layer ZM is not provided.

In addition, the arm region AR is provided over a portion which overlaps the partition wall of the pressure chamber substrate 34 between two adjacent pressure chambers CV and a portion which overlaps a part of the pressure chamber CV in plan view. In the following description, with m being any integer from 1 to M-1, the arm region AR provided between the pressure chamber CV[m] and the pressure chamber CV[m+1] in plan view may be referred to as an arm region AR[m]. In addition, the arm regions AR[1] to AR[M-1] may be referred to as arm regions AR without distinction. The arm region AR has a polygonal shape having a direction along the X-axis as a longitudinal direction, and is a hexagonal shape in the first embodiment. In the following description, with m being any integer from 1 to M-1, in plan view, among six sides of the arm region AR[m], two sides intersecting an X1 direction end of the first film 431 and two sides intersecting an X2 direction end of the second film 432 may be referred to as short sides SD, and two sides extending in a direction along the Y-axis may be referred to as long sides SL. It can also be said that the four short sides SD have a component in a direction along the Y-axis among the six sides of the arm region AR.

In addition, with m being any integer from 1 to M-1, in plan view, among two short sides SD of the arm region AR[m] that intersect an X2 direction end of the second film 432, a short side SD intersecting a wall surface WY1[m+1] located in the Y1 direction of the pressure chamber CV[m+1] may be referred to as a short side SD1, and a short side SD intersecting a wall surface WY2[m] located in the Y2 direction of the pressure chamber CV[m] may be referred to as a short side SD2. Of the two long sides SL of the arm region AR[m], a long side SL in the pressure chamber CV[m+1] may be referred to as a long side SL1. In plan view, it can be said that the wall surface of the pressure chamber CV is a boundary line between an overlapping region SA and a non-overlapping region IA.

The short sides SD1 and SD2 and the long sides SL1 and SL1 are provided so as to be line-symmetric with respect to the X-axis in plan view.

The short side SD1 extends in a direction along a W-axis perpendicular to the Z-axis. The direction along the W-axis is a general term for a W1 direction and a W2 direction opposite to the W1 direction. The W1 direction is a direction between the X1 direction and the Y1 direction. The W2 direction is a direction between the X2 direction and the Y2 direction. In addition, a direction perpendicular to the Z-axis and the W-axis may be described as a direction along a V-axis. The direction along the V-axis is a general term for a V1 direction and a V2 direction opposite to the V1 direction. The V1 direction is a direction between the Y1 direction and the X2 direction. The V2 direction is a direction between the X1 direction and the Y2 direction. The line VII-VII illustrated in FIG. 6 is a line parallel to the V-axis and orthogonal to the short side SD1. The VIII-VIII line illustrated in FIG. 6 is a line parallel to the Y-axis and orthogonal to the long side SL1.

In the following description, in the direction along the Y-axis, a region in which the pressure chamber CV and the vibrating plate 36 overlap each other when viewed in the Z2 direction may be referred to as an overlapping region SA, and a region in which a partition wall partitioning the pressure chamber CV in the pressure chamber substrate 34 and the vibrating plate 36 overlap each other may be referred to as a non-overlapping region IA. The direction along the Y-axis is an example of a "width direction" and is also a short direction of the pressure chamber CV. In plan view, the arm region AR is located from a part of the overlapping region SA to a part of the non-overlapping region IA. Specifically, with m being any integer from 1 to M-1, the arm region AR[m] overlaps, in plan view, with an end portion in the Y2 direction of the pressure chamber CV[m] and an end portion in the Y1 direction of the pressure chamber CV[m+1] as a part of the overlapping region SA. As illustrated in FIG. 6, the lower electrode ZD does not overlap the arm region AR in plan view. On the other hand, the upper electrode ZU overlaps the arm region AR in plan view.

As illustrate in FIG. 6, in plan view, with m being any integer from 1 to M-1, an angle θ1 formed by the short side SD2 of the arm region AR[m] and a imaginary line LV1 along a wall surface WY2[m] located in the Y2 direction of the pressure chamber CV[m] is 20 degrees or more and 45 degrees or less, and is preferably 25 degrees or more and 32 degrees or less.

In addition, the stress relieving portion SR for relieving stress applied to the arm region AR is provided over the entire circumference of the polygonal shape of the arm region AR. Specifically, as understood from FIGS. 7 and 8, a groove portion GL is provided along the entire circumference of the polygonal shape of the arm region AR. The stress relieving portion SR is provided along the groove portion GL. The stress relieving portion SR is provided on the upper electrode ZU. Specifically, the stress relieving portion SR is provided so as to fill the groove portion GL. Hereinafter, among the groove portions GL provided along the entire circumference of the polygonal shape of the arm region AR, the groove portion GL provided on the short side SD1 may be referred to as a groove portion GLS1, and the groove portion GL provided on the long side SL1 may be referred to as a groove portion GLL1. Further, the stress relieving portion SR provided along the short side SD1 may be referred to as a first stress relieving portion SRS1. Further, the stress relieving portion SR provided on the long side SL1 may be referred to as a second stress relieving portion SRL1. The first stress relieving portion SRS1 and the second stress relieving portion SRL1 may be collectively referred to as a stress relieving portion SR without distinction. As understood from FIGS. 7 and 8, a depth DL1 of the groove portion GLL1 is longer than a depth DS1 of the groove portion GLS1. The short side SD1 is an example of a "first side", and the long side SL1 is an example of a "second side". The direction along the W-axis along which the short side SD1 extends is an example of a "second direction". The first stress relieving portion SRS1 is an example of a "first stress relieving portion", and the second stress relieving portion SRL1 is an example of a "second stress relieving portion". The groove portion GLS1 is an example of a "first groove portion", and the groove portion GLL1 is an example of a "second groove portion".

As illustrated in FIGS. 7 and 8, the groove portion GL is formed by a recessed portion RC in which the insulating layer 362 is recessed in the Z2 direction. The recessed portion RC does not reach the elastic layer 361. Specifically, the groove portion GLS1 is formed by a recessed portion RCS1. The groove portion GLL1 is formed by a recessed portion RCL1. The depth of the groove portion GL, that is, a length of the groove portion GL in the direction along the Z-axis is, for example, 50 nm or less, and specifically, several tens of nm. nm means nanometer.

The stress relieving portion SR is formed of, for example, an inorganic material or an organic material that can relieve stress. The stress relieving portion SR is preferably formed of an organic material in consideration of the fact that an organic material tends to have a lower Young's modulus than an inorganic material and the fact that the effect of dispersing stress is increased when the Young's modulus is small. For example, the stress relieving portion SR is formed of a polyimide resin or an epoxy resin. The first stress relieving portion SRS1 and the second stress relieving portion SRL1 may be formed of the same material or different materials.

The stress relieving portion SR is preferably formed of a material having high fluidity when formed. When the fluidity of the precursor material of the stress relieving portion SR is high, when the stress relieving portion SR is formed, the precursor material easily flows into the groove portion GL by a capillary phenomenon, and the stress relieving portion SR can be uniformly formed along the groove portion GL.

A method of forming the stress relieving portion SR is optional. For example, the stress relieving portion SR may be formed by a wet method or a vapor deposition method.

The first stress relieving portion SRS1 is provided along the short side SD1. The second stress relieving portion SRL1 is provided along the long side SL1.

That the first stress relieving portion SRS1 is provided along the short side SD1 may mean that the first stress relieving portion SRS1 is provided over the entire short side SD1, or a portion where the first stress relieving portion SRS1 is present and a portion where the first stress relieving portion SRS1 is not present may be scattered along the short side SD1. Similarly, that the second stress relieving portion SRL1 is provided along the long side SL1 means that the second stress relieving portion SRL1 may be provided over an entire length of the long side SL1, or a portion where the second stress relieving portion SRL1 is present and a portion where the second stress relieving portion SRL1 is not present may be scattered along the long side SL1.

From the viewpoint of relieving stresses, it is preferable that the first stress relieving portion SRS1 is provided over the entire short side SD1. In addition, it is preferable that the second stress relieving portion SRL1 is provided over the entire long side SL1 from the viewpoint of suppressing the variation in the displacement efficiencies of the piezoelectric elements PZ.

In addition, it is preferable that the first stress relieving portion SRS1 and the second stress relieving portion SRL1 are continuously formed without gaps. As a result, since no gap is formed between the first stress relieving portion SRS1 and the second stress relieving portion SRL1, it is possible to suppress occurrence of variations in how stress is applied depending on presence or absence of the stress relieving portion SR. In addition, since the stress relieving portion SR is provided at a corner portion where the short side SD1 and the long side SL1 are in contact with each other, it is possible to suppress the occurrence of a crack at the corner portion.

Although not illustrated in the drawings, the stress relieving portions SR may also be provided on three short sides SD other than the short side SD1 among the four short sides SD of the arm region AR. Similarly, the stress relieving portion SR may be provided also on the long side SL other than the long side SL1 of the two long sides SL of the arm region AR.

As illustrated in FIG. 7, the piezoelectric layer ZM has an inclined portion ZMS1 which is inclined with respect to the vibrating plate 36 when viewed in the W1 direction. The inclined portion ZMS1 has a surface FS1 facing in a U1 direction. The U1 direction is orthogonal to the direction along the W-axis and is a direction between the V1 direction and the Z1 direction. The U1 direction has a component in the Z1 direction and a component in the V1 direction. When viewed in the W1 direction, an angle θS1 formed by the surface FS1 and a surface 36S of the vibrating plate 36 facing the Z1 direction is 15 degrees or more and 45 degrees or less, and is preferably about 30 degrees. In addition, as illustrated in FIG. 8, the piezoelectric layer ZM has an inclined portion ZML1 which is inclined with respect to the vibrating plate 36 when viewed in the X1 direction. The inclined portion ZML1 has a surface FL1 facing in a S1 direction. The S1 direction is orthogonal to the direction along the X-axis and is a direction between the Y1 direction and the Z1 direction. The S1 direction has components in the Z1 direction and components in the Y1 direction. An angle θL1 formed by the surface FL1 and the surface 36S when viewed in the X1 direction is 15 degrees or more and 45 degrees or less, and is preferably about 30 degrees. The angle θS1 and the angle θL1 may be equal to or different from each other. The surface 36S is an example of a "second surface". The inclined portion ZMS1 corresponds to an "inclined portion", the U1 direction corresponds to a "third direction", and the surface FS1 corresponds to a "first surface".

### 1-4. Summary of First Embodiment

In the first embodiment, the piezoelectric device PD includes the vibrating plate 36 that is coupled to the pressure chamber substrate 34 and partitions the pressure chamber CV together with the pressure chamber substrate 34, the upper electrode ZU, the piezoelectric layer ZM, and the lower electrode ZD, which are laminated in this order along the Z2 direction from the vibrating plate 36 toward the pressure chamber substrate 34, and the piezoelectric element PZ disposed on a side of the vibrating plate 36 opposite to the pressure chamber CV. When a region in which the pressure chamber CV and the vibrating plate 36 overlap when viewed in the Z2 direction is defined as an overlapping region SA, and a region in which a partition wall that partitions the pressure chamber CV among the pressure chamber substrate 34 and the vibrating plate 36 overlap when viewed in the Z2 direction is defined as a non-overlapping region IA, the arm region AR, which is a region in which the piezoelectric layer ZM is not provided when viewed in the Z2 direction, is located so as to extend from a part of the overlapping region SA to a part of the non-overlapping region IA, and a first stress relieving portion SRS1 is provided along a direction along a W-axis that intersects the X-axis, which is a longitudinal direction of the arm region AR.

By providing the arm region AR, it is possible to increase the displacement efficiency when the piezoelectric layer ZM is displaced. On the other hand, since the piezoelectric layer ZM is not provided in the arm region AR, there is a possibility that stress is concentrated at the end portion of the arm region AR due to the displacement of the piezoelectric layer ZM and a crack is generated. Further, among sides of the arm region AR, a displacement change amount due to displacement of the piezoelectric element PZ becomes larger as the length becomes shorter. Therefore, the displacement change amount at the side intersecting the longitudinal direction of the arm region AR is larger than the displacement change amount at the side in the longitudinal direction of the arm region AR. As described above, according to the present embodiment, the first stress relieving portion SRS1 is provided in the direction intersecting the longitudinal direction of the arm region AR in which the displacement change amount is large, that is, at a location where a crack is likely to occur, and thus it is possible to suppress a possibility that a crack occurs.

The short side SD1 along the W-axis of the arm region AR intersects the wall surface of the pressure chamber CV, which is the boundary line between the overlapping region SA and the non-overlapping region IA, when viewed in the Z2 direction, and the first stress relieving portion SRS1 is provided along the short side SD1.

The arm region AR has the short side SD1 that is provided so as to extend across the pressure chamber CV and the partition wall of the pressure chamber substrate 34 when viewed in the Z2 direction. At this time, when viewed in the Z2 direction, there is a possibility that stress is concentrated at a location where the short side SD1 and the boundary between the pressure chamber CV and the partition wall of the pressure chamber substrate 34 overlap each other, and a crack is generated. Further, when viewed in the Z2 direction, the pressure chamber CV also extends in the direction along the X-axis similarly to the arm region AR, and the length of the short side SD of the arm region AR intersecting the wall surface of the pressure chamber CV is shorter than the length of the long side SL in the longitudinal direction of the arm region AR. Therefore, by providing the first stress relieving portion SRS1 on the short side SD of the arm region AR, it is possible to suppress the possibility that a crack occurs.

In addition, the piezoelectric layer ZM is removed by processing such as etching in a portion positioned on a side of the arm region AR. In such a case, the shape becomes unstable due to an error in etching or the like, and as a result, variations in how stress is applied tend to occur for each piezoelectric element PZ. Therefore, since the stress relieving portion SR is provided on the side of the arm region AR, it is possible to suppress a variation in each piezoelectric element PZ due to etching or the like.

When viewed in the Z2 direction, the arm region AR has a polygonal shape, and among an entire circumference of the polygonal shape, the long side SL1 extending in a direction along the X-axis that is different from a direction along the W-axis is provided with the second stress relieving portion SRL1.

According to the first embodiment, since not only the first stress relieving portion SRS1 but also the second stress relieving portion SRL1 is provided, it is possible to suppress variations in how stress is applied in the arm region AR compared with an aspect in which only the first stress relieving portion SRS1 is provided.

When viewed in the Z2 direction, with m being any integer from 1 to M-1, an angle θ1 formed by a short side SD2 of the arm region AR[m] and an imaginary line LV1 along which a wall surface WY2[m] of partition walls of the pressure chamber substrate 34 and with which the short side SD2 intersects, extends, is 20 degrees or more and 45 degrees or less. Similarly, an angle formed by the short side SD1 of the arm region AR[m] and an imaginary line along which a wall surface WY1[m+1], of partition walls of the pressure chamber substrate 34 with which the short side SD1 intersects, extends, is 20 degrees or more and 45 degrees or less.

As described above, when the angle formed by the short side SD1 and the imaginary line along the wall surface WY1 is larger than 45 degrees, the amount of change in the stresses applied to the short side SD1 becomes steep in the vicinity of the intersection between the short side SD1 and the wall surface WY2[m] when viewed in the Z2 direction, so that a crack is likely to occur. On the other hand, when the angle is less than 20 degrees, the arm region AR becomes large in the direction along the X-axis, and thus the piezoelectric element PZ becomes large. Therefore, according to the first embodiment, it is possible to suppress an increase in size of the piezoelectric element PZ while making cracks less likely to occur.

In addition, when viewed in the W1 direction orthogonal to the Z2 direction, the piezoelectric layer ZM has an inclined portion ZMS1 that is inclined such that an angle θS1 formed by the surface FS1 facing the U1 direction including a component in the Z1 direction of the piezoelectric layer ZM and the surface 36S facing the Z1 direction of the vibrating plate 36 is 15 degrees or more and 45 degrees or less. The short side SD1 of the arm region AR is a side at which the surface FS1 is in contact with the surface 36S when viewed in the Z2 direction.

When the angle θS1 is less than 15 degrees, the piezoelectric layer ZM is increased in size when viewed in the Z2 direction. On the other hand, when the angle θS1 is larger than 45 degrees, since the angle of the piezoelectric layer ZM becomes steep, displacement applied to the vicinity of the short side SD1 becomes steep, and the concentration of stress is likely to occur. Therefore, according to the first embodiment, it is possible to suppress an increase in size of the piezoelectric element PZ while reducing the concentration of stress.

Further, in the arm region AR, the groove portion GLS1 recessed in the Z2 direction is provided along the short side SD1, and the first stress relieving portion SRS1 is provided in the groove portion GLS1.

According to the first embodiment, when a material for forming the first stress relieving portion SRS1 is provided by a material having high fluidity, it is possible to easily form the first stress relieving portion SRS1 along the short side SD1 because the groove portion GLS1 is provided. In addition, since the groove portion GLS1 is provided, it is possible to stabilize the position where the first stress relieving portion SRS1 is provided.

In addition, the groove portion GLL1 which is recessed in the Z2 direction is provided on a side of the arm region AR which overlaps the overlapping region SA when viewed in the Z2 direction.

According to the first embodiment, compared to an aspect in which the groove portion GLL1 is not provided, the vibrating plate 36 easily expands and contracts in the overlapping region SA, and it is possible to improve a displacement amount of the vibrating plate 36.

The depth DL1 of the groove portion GLL1 in the Z2 direction is longer than the depth DS1 of the groove portion GLS1 in the Z2 direction.

According to the first embodiment, it is possible to improve the displacement amount of the vibrating plate 36 compared to an aspect in which the groove portion GLS1 is deeper than the groove portion GLL1.

In addition, the vibrating plate 36 includes the elastic layer 361 which is formed of silicon oxide as a main constituent material, and the insulating layer 362 which is positioned closer to the piezoelectric elements PZ than the elastic layer 361 in the Z2 direction and is formed of a constituent material different from that of the elastic layer 361, and the groove portion GLS1 is formed by a recessed portion RCS1 in which the insulating layer 362 is recessed in the Z2 direction.

According to the first embodiment, since the recessed portion RCS1 is provided only in the insulating layer 362 and the interface between the elastic layer 361 and the insulating layer 362 is not exposed, it is possible to suppress diffusion of moisture from the pressure chamber CV to the interface or diffusion of lead from the piezoelectric layer ZM to the elastic layer 361.

In addition, the lower electrode ZD is provided closer to the vibrating plate 36 than the upper electrode ZU, the lower electrode ZD does not overlap the arm region AR when viewed in the Z2 direction, the upper electrode ZU overlaps the arm region AR when viewed in the Z2 direction, and the first stress relieving portion SRS1 is provided on the upper electrode ZU.

According to the first embodiment, since the upper electrode ZU is provided from the overlapping region SA to the arm region AR, the upper electrode ZU covers the boundary between the piezoelectric layer ZM and the vibrating plate 36 in the arm region AR, and thus it is possible to further relieve the stress at the boundary. In addition, since the first stress relieving portion SRS1 is not in direct contact with the piezoelectric layer ZM, it is possible to improve freedom in selecting the material of the first stress relieving portion SRS1.

The first stress relieving portion SRS1 is formed of an organic material.

In general, an organic material tends to have a lower Young's modulus than an inorganic material. When the Young's modulus is small, the effect of dispersing the stress increases. Therefore, according to the first embodiment, as compared with the aspect in which the first stress relieving portion SRS1 is formed of an inorganic material, the effect of dispersing stress is increased, and it is possible to reduce a possibility that a crack occurs.

The piezoelectric device PD may further include the sealing member 44 for sealing the piezoelectric element PZ, and the adhesive for bonding the sealing member 44 to the vibrating plate 36 and the first stress relieving portion SRS1 may be formed of the same material.

According to this configuration, by performing the process of bonding the sealing member 44 to the vibrating plate 36, the first stress relieving portion SRS1 can also be formed at the same time. Therefore, the process of forming the piezoelectric device PD can be simplified as compared with an aspect in which the process of bonding the sealing member 44 to the vibrating plate 36 and the process of forming the first stress relieving portion SRS1 are performed separately.

The liquid ejection head 10 according to the first embodiment includes the piezoelectric device PD.

### 2. Second Embodiment

In the first embodiment, the lower electrode ZD is the individual electrode, and the upper electrode ZU is the common electrode, but the present disclosure is not limited thereto, and the lower electrode may be the common electrode, and the upper electrode may be the individual electrode. Hereinafter, a second embodiment will be described.

### 2-1. Configuration of Piezoelectric Device PDa in Second Embodiment

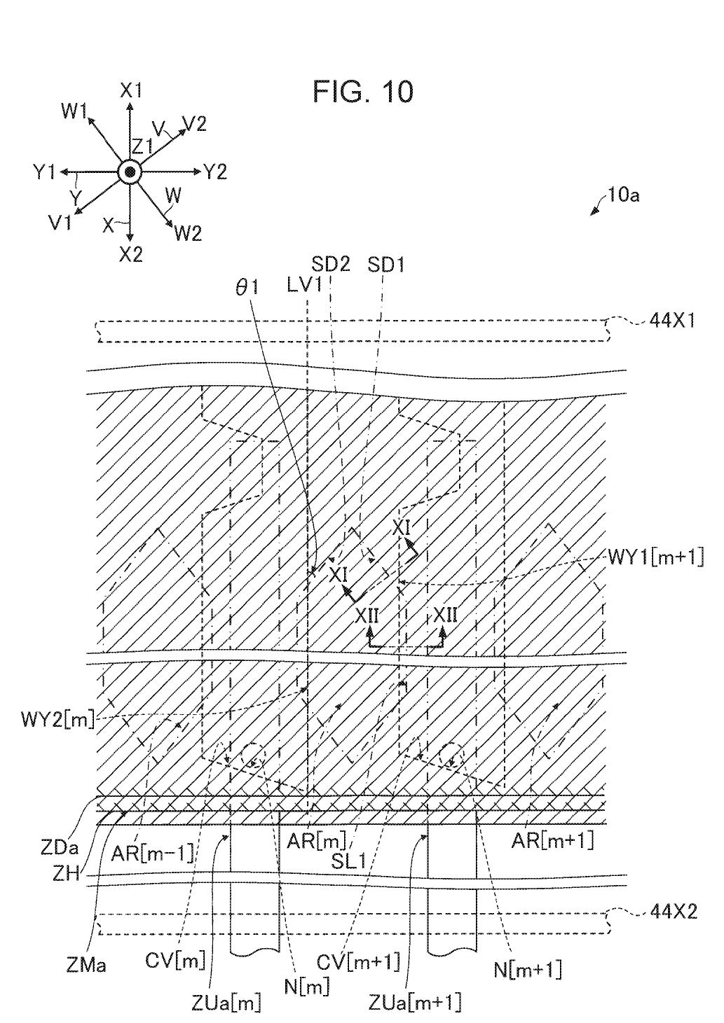

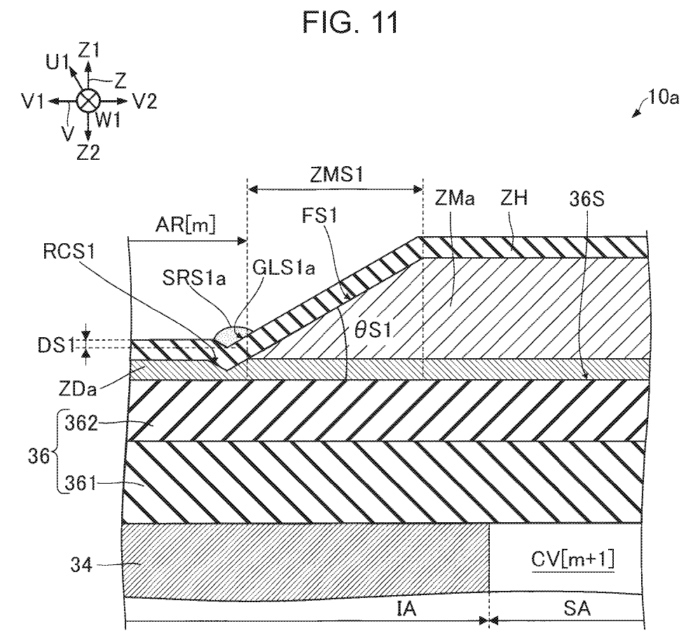

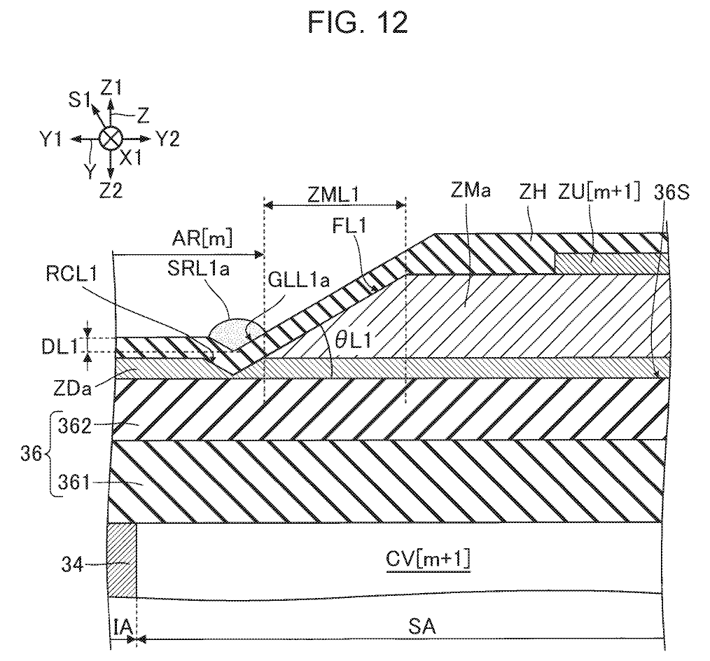

FIG. 9 is an enlarged sectional view of the vicinity of a piezoelectric device PDa. FIG. 10 is an enlarged view of the range RG illustrated in FIG. 4 in a liquid ejection head 10a according to the second embodiment. However, in order to prevent the drawing from being complicated, the sealing member 44 is not illustrated in FIG. 10. FIG. 11 is a sectional view taken along line XI-XI in FIG. 10. FIG. 12 is a sectional view taken along line XII-XII in FIG. 10.

The liquid ejection head 10a is different from the liquid ejection head 10 in that it includes the piezoelectric device PDa instead of the piezoelectric device PD. The piezoelectric device PDa is different from the piezoelectric device PD in that it includes a lower electrode ZDa instead of the lower electrode ZD, a piezoelectric layer ZMa instead of the piezoelectric layer ZM, an upper electrode ZUa instead of the upper electrode ZU, and a protective film ZH. In FIGS. 9 and 10, in order to prevent the drawings from being complicated, display and description of the deformation restricting portion 43 are omitted. In FIG. 10, in order to prevent the drawings from being complicated, hatching of the piezoelectric layer ZMa and the protective film ZH is partially omitted.

The lower electrode ZDa is different from the lower electrode ZD in that the reference potential VBS is supplied. The upper electrode ZUa is different from the upper electrode ZU in that the drive signal Com is supplied. The lower electrode ZDa is commonly provided for the M pressure chambers CV. Therefore, the lower electrode ZDa is also referred to as a common electrode. On the other hand, the upper electrode ZUa is individually provided for the M pressure chambers CV. Therefore, the upper electrode ZUa is also referred to as an individual electrode. The upper electrode ZUa does not overlap the arm region AR in plan view. The lower electrode ZDa overlaps the arm region AR in plan view. In the second embodiment, the lower electrode ZDa is an example of the "first electrode", and the upper electrode ZUa is an example of the "second electrode".

Since the upper electrode ZUa is an individual electrode, the piezoelectric layer ZMa differs from the piezoelectric layer ZM in that the piezoelectric layer ZMa has a portion exposed from the upper electrode ZUa. The protective film ZH is provided on a side of the piezoelectric layer ZMa opposite to the upper electrode ZUa. In the example of FIG. 10, the protective film ZH covers a portion of the piezoelectric layer ZMa exposed from the upper electrode ZUa and the entire arm region AR. Since the piezoelectric layer ZMa is not provided in the arm region AR, in plan view, the protective film ZH may be provided in a range of the arm region AR to an extent that moisture entering the piezoelectric layer ZMa from a direction orthogonal to the Z-axis can be suppressed, and the protective film ZH may not be provided in other ranges, specifically, in a central portion of the arm region AR. That is, the protective film ZH may cover a portion of the piezoelectric layer ZMa exposed from the upper electrode ZUa and at least a part of the arm region AR.

As a material of the protective film ZH, a material having moisture resistance may be used, and for example, it is preferable to use an inorganic insulating material such as silicon oxide (SiOₓ), tantalum oxide (TaOₓ), aluminum oxide (AlOₓ), and it is particularly preferable to use aluminum oxide (AlOₓ), which is an inorganic amorphous material, for example, alumina (Al₂O₃).

The second embodiment is different from the first embodiment in that the groove portion GL is formed by a recessed portion RC in which the lower electrode ZDa is recessed in the Z2 direction. The recessed portion RC does not reach the insulating layer 362. Specifically, a groove portion GLS1a is formed by the recessed portion RCS1. A groove portion GLL1a is formed by the recessed portion RCL1. The groove portions GLS1a and GLL1a are covered with the protective film ZH.

As understood from FIGS. 11 and 12, the stress relieving portion SRa in the second embodiment is provided on the protective film ZH. As illustrated in FIG. 11, the stress relieving portion SRa provided along the short side SD1 may be referred to as a first stress relieving portion SRS1a. Further, as illustrated in FIG. 12, the stress relieving portion SRa provided along the long side SL1 may be referred to as a second stress relieving portion SRL1a. In the second embodiment, the first stress relieving portion SRS1a is an example of the "first stress relieving portion", and the second stress relieving portion SRL1a is an example of the "second stress relieving portion".

### 2-2. Summary of Second Embodiment

As described above, in the piezoelectric device PD according to the second embodiment, the lower electrode ZDa is provided closer to the vibrating plate 36 than the upper electrode ZUa, and the piezoelectric element PZa further has the protective film ZH provided on a side of the piezoelectric layer ZMa opposite to the upper electrode ZUa. When viewed in the Z2 direction, the upper electrode ZUa does not overlap the arm region AR, and when viewed in the Z2 direction, the lower electrode ZDa overlaps the arm region AR, the protective film ZH covers the piezoelectric layer ZMa exposed from the upper electrode ZUa as well as at least a part of the arm region AR, and the first stress relieving portion SRS1a is provided on the protective film ZH.

According to the second embodiment, since the protective film ZH is provided from the overlapping region SA to at least a part of the arm region AR, the protective film ZH covers the boundary between the piezoelectric layer ZMa and the vibrating plate 36 in the arm region AR, and thus it is possible to further relieve the stress at the boundary. In addition, since the first stress relieving portion SRS1a is not in direct contact with the piezoelectric layer ZMa, it is possible to improve the freedom in selecting the material of the first stress relieving portion SRS1a.

### 3. Modification Examples

The above embodiments can be variously modified. Specific modification aspects that can be applied to each of the above embodiments will be described below. Any two or more aspects selected from the following examples can be combined as appropriate as long as there is no contradiction.

### 3-1. First Modification Example

In each of the above aspects, the second stress relieving portion SRL1 may not be provided.

### 3-2. Second Modification Example

In each of the above aspects, the angle θ1 may be less than 20 degrees or larger than 45 degrees. In addition, the angle θS1 and the angle θL1 may be less than 15 degrees or larger than 45 degrees.

### 3-3. Third Modification Example

In each of the above aspects, the groove portion GLS1 may be deeper than the groove portion GLL1. In addition, one or both of the groove portion GLS1 and the groove portion GLL1 may not be provided.

### 3-4. Fourth Modification Example

In each of the above aspects, the groove portion GLS1 and the groove portion GLL1 are formed by the recessed portion RC in which the insulating layer 362 is recessed in the Z2 direction, but the present disclosure is not limited thereto. For example, the groove portion GLS1 and the groove portion GLL1 may be formed by a recessed portion which penetrates the insulating layer 362 and in which the elastic layer 361 is recessed in the Z2 direction.

### 3-5. Fifth Modification Example

In each of the above aspects, the adhesive for bonding the sealing member 44 to the vibrating plate 36 and the first stress relieving portion SRS1 may be formed of different materials. For example, one of the adhesive for bonding the sealing member 44 to the vibrating plate 36 and the first stress relieving portion SRS1 may be formed of an epoxy adhesive, and the other may be formed of a silicone adhesive containing a silicone resin as a main component.

### 3-6. Sixth Modification Example

In each aspect described above, a serial type liquid ejection apparatus in which the housing case 71 on which the liquid ejection head 10 is mounted is reciprocated is exemplified, but the present disclosure can also be applied to a line type liquid ejection apparatus in which a plurality of nozzles N are distributed over the entire width of the medium PP.

### 3-7. Seventh Modification Example

The above-described liquid ejection apparatus can be employed in various apparatuses such as a facsimile machine and a copier, in addition to an apparatus dedicated to printing. However, the application of the liquid ejection apparatus of the present disclosure is not limited to printing. For example, a liquid ejection apparatus that ejects a solution of a coloring material is used as a manufacturing apparatus that forms a color filter of a liquid crystal display device. Further, the liquid ejection apparatus that ejects a solution of a conductive material is used as a manufacturing apparatus that forms wiring and electrodes of a wiring substrate.

### 3-8. Eighth Modification Example

The piezoelectric device PD described above can be mounted not only on the liquid ejection head 10 and the liquid ejection apparatus 100, but also on any of a device that generates a mechanical force when a voltage is applied thereto, a device that generates a voltage when a mechanical force is applied thereto, and a device having a function of converting a voltage into a mechanical force. The piezoelectric device PC according to the present disclosure can be mounted on, for example, an ultrasonic motor, a vibration-type dust removing device, a piezoelectric transformer, a piezoelectric speaker, a piezoelectric pump, an ultrasonic detector, an angular velocity sensor, an accelerometer, a vibration sensor, a tilt sensor, a pressure sensor, a collision sensor, a motion sensor, an infrared sensor, a terahertz sensor, a heat detection sensor, a pyroelectric sensor, a piezoelectric sensor, a ferroelectric memory (FeRAM), a ferroelectric transistor (FeFET), a ferroelectric arithmetic circuit (FeLogic), a ferroelectric capacitor, a wavelength converter, an optical waveguide, an optical path modulator, a refractive index control element, an electronic shutter mechanism, or the like.

What is claimed is:

1. A piezoelectric device comprising:
a vibrating plate coupled to a first substrate and configured to partition a space together with the first substrate; and a piezoelectric element in which a first electrode, a piezoelectric layer, and a second electrode are laminated in this order along a first direction from the vibrating plate toward the first substrate, the piezoelectric element being disposed on a side of the vibrating plate opposite to the space, wherein when a region in which the space and the vibrating plate overlap each other when viewed in the first direction is defined as an overlapping region, and a region in which a partition wall of the first substrate that partitions the space and the vibrating plate overlap each other when viewed in the first direction is defined as a non-overlapping region, an arm region, which is a region in which the piezoelectric layer is not provided when viewed in the first direction, is located from a part of the overlapping region to a part of the non-overlapping region, and a first stress relieving portion is provided along a second direction intersecting a longitudinal direction of the arm region in the arm region.

2. The piezoelectric device according to claim 1, wherein
a first side of the arm region along the second direction intersects a boundary line between the overlapping region and the non-overlapping region when viewed in the first direction, and
the first stress relieving portion is provided along the first side.

3. The piezoelectric device according to claim 2, wherein
when viewed in the first direction, the arm region has a polygonal shape, and
a second stress relieving portion is provided along a side of the polygonal shape that extends in a direction different from the second direction.

4. The piezoelectric device according to claim 2, wherein
when viewed in the first direction, an angle between the first side and a imaginary line extending along a wall surface of the partition wall that intersects the first side is 20 degrees or more and 45 degrees or less.

5. The piezoelectric device according to claim 2, wherein
when viewed in a direction orthogonal to the first direction, the piezoelectric layer includes an inclined portion having a first surface and a second surface, an angle between the first surface and the second surface being 15 degrees or more and 45 degrees or less, the first surface facing in a third direction having a component opposite to the first direction and the second surface facing toward the vibrating plate; and
when viewed in the first direction, an edge at which the first surface meets the second surface extends along the first side.

6. The piezoelectric device according to claim 2, wherein
in the arm region, a first groove portion recessed in the first direction is provided along the first side, and
the first stress relieving portion is provided in the first groove portion.

7. The piezoelectric device according to claim 6, wherein
a second groove portion recessed in the first direction is provided on a second side which is different from the first side, a second groove portion overlapping the overlapping region in the arm region when viewed in the first direction and extending along the longitudinal direction.

8. The piezoelectric device according to claim 7, wherein
a length of the second groove portion in the first direction is longer than a length of the first groove portion in the first direction.

9. The piezoelectric device according to claim 6, wherein
the vibrating plate includes
a first layer formed of silicon oxide as a main constituent material, and
a second layer located closer to the piezoelectric element than the first layer in the first direction and formed of a constituent material different from that of the first layer, and
the first groove portion is formed by a recessed portion in which the second layer is recessed in the first direction.

10. The piezoelectric device according to claim 1, wherein
when viewed in the first direction, the second electrode does not overlap the arm region,
when viewed in the first direction, the first electrode overlaps the arm region, and
the first stress relieving portion is provided on the first electrode.

11. The piezoelectric device according to claim 1, wherein
the piezoelectric element further includes a protective film provided on a side of the piezoelectric layer opposite to the second electrode,
when viewed in the first direction, the first electrode does not overlap the arm region,
when viewed in the first direction, the second electrode overlaps the arm region,
the protective film covers a portion of the piezoelectric layer exposed from the first electrode and at least a part of the arm region, and
the first stress relieving portion is provided on the protective film.

12. The piezoelectric device according to claim 1, wherein
the first stress relieving portion is formed of an organic material.

13. The piezoelectric device according to claim 1, further comprising:
a sealing member configured to seal the piezoelectric element, wherein
an adhesive for bonding the sealing member to the vibrating plate and the first stress relieving portion are formed of the same material.

14. A liquid ejection head comprising:
the piezoelectric device according to claim 1.
